(19) United States
(12) Patent Application Publication
(10) Pub. No.: US 2020/0210105 A1
(43) Pub. Date: Jul. 2, 2020

(54) ACCELERATED MEMORY DEVICE TRIM INITIALIZATION

(71) Applicant: Micron Technology, Inc., Boise, ID (US)

(72) Inventors: Fulvio Rori, Boise, ID (US); Chiara Cerafogli, Boise, ID (US); Giuseppe Cariello, Boise, ID (US); Jonathan Parry, Boise, ID (US)

(21) Appl. No.: 16/235,925

(22) Filed: Dec. 28, 2018

(51) Int. Cl. G06F 3/06

(52) U.S. Cl. CPC G06F 3/0659; G11C 16/0483; G06F 3/0679; G06F 3/0604

(57) ABSTRACT

Devices and techniques for accelerated memory device trim initialization are described herein. An initialization of a memory device can be started by the memory device. An accelerated trim command can be received at the memory device from a controller. The memory device can refrain from setting a trim in response to receipt of the accelerated trim command. Here, the trim is expected to be set by the controller. The memory device can then complete the initialization after the trim is set by the controller.

### BACKGROUND

Memory devices are typically provided as internal, semiconductor, integrated circuits in computers or other electronic devices. There are many different types of memory, including volatile and non-volatile memory.

Volatile memory requires power to maintain its data, and includes random-access memory (RAM), dynamic random-access memory (DRAM), or synchronous dynamic random-access memory (SDRAM), among others.

Non-volatile memory can retain stored data when not powered, and includes flash memory, read-only memory (ROM), electrically erasable programmable ROM (EEPROM), static RAM (SRAM), erasable programmable ROM (EPROM), resistance variable memory, such as phase-change random-access memory (PCRAM), resistive random-access memory (RRAM), or magnetoresistive random-access memory (MRAM), ferroelectric random-access memory (FeRAM), among others.

Flash memory is utilized as non-volatile memory for a wide range of electronic applications. Flash memory devices typically include one or more groups of one-transistor, floating gate or charge trap memory cells that allow for high memory densities, high reliability, and low power consumption.

Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a bit line.

Both NOR and NAND architecture semiconductor memory arrays are accessed through decoders that activate specific memory cells by selecting the word line coupled to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines coupled to the gates of the unselected memory cells of each group are driven at a specified pass voltage (e.g., Vpass) to operate the unselected memory cells of each group as pass transistors (e.g., to pass current in a manner that is unrestricted by their stored data values). Current then flows from the source line to the bit line through each series coupled group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data.

However, flash memory cells can also represent one of more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context, to can refer to any memory cell that can store more than one bit of data per cell (i.e., that can represent more than two programmed states).

Traditional memory arrays are two-dimensional (2D) structures arranged on a surface of a semiconductor substrate. To increase memory capacity for a given area, and to decrease cost, the size of the individual memory cells has decreased. However, there is a technological limit to the reduction in size of the individual memory cells, and thus, to the memory density of 2D memory arrays. In response, three-dimensional (3D) memory structures, such as 3D NAND architecture semiconductor memory devices, are being developed to further increase memory density and lower memory cost.

Such 3D NAND devices often include strings of storage cells, coupled in series (e.g., drain to source), between one or more source-side select gates (SGSs) proximate a source, and one or more drain-side select gates (SGDs) proximate a bit line. In an example, the SGSs or the SGDs can include one or more field-effect transistors (FETs) or metal-oxide semiconductor (MOS) structure devices, etc. In some examples, the strings will extend vertically, through multiple vertically spaced tiers containing respective word lines. A semiconductor structure (e.g., a polysilicon structure) can extend adjacent a string of storage cells to form a channel for the storages cells of the string. In the example of a vertical string, the polysilicon structure can be in the form of a vertically extending pillar. In some examples the string can be “folded,” and thus arranged relative to a U-shaped pillar. In other examples, multiple vertical structures can be stacked upon one another to form stacked arrays of storage cell strings.

Memory arrays or devices can be combined together to form a storage volume of a memory system, such as a solid-state drive (SSD), a Universal Flash Storage (UFS™) device, a MultiMediaCard (MMC) solid-state storage device, an embedded MMC device (eMMC™), etc. An SSD can be used as, among other things, the main storage device of a computer, having advantages over traditional hard drives with moving parts with respect to, for example, performance, size, weight, ruggedness, operating temperature range, and power consumption. For example, SSDs can have reduced seek time, latency, or other delay associated with magnetic disk drives (e.g., electromechanical, etc.). SSDs use non-volatile memory cells, such as flash memory cells to obviate internal battery supply requirements, thus allowing the drive to be more versatile and compact.

An SSD can include a number of memory devices, including a number of dies or logical units (e.g., logical unit numbers or LUNs), and can include one or more processors or other controllers performing logic functions required to operate the memory devices or interface with external systems. Such SSDs can include one or more flash memory die, including a number of memory arrays and peripheral circuitry thereon. The flash memory arrays can include a number of blocks of memory cells organized into a number of physical pages. In many examples, the SSDs will also include DRAM or SRAM (or other forms of memory die or other memory structures). The SSD can receive commands from a host in association with memory operations, such as read or write operations to transfer data (e.g., user data and associated integrity data, such as error data and address data, etc.) between the memory devices and the host, or erase operations to erase data from the memory devices.

### BRIEF DESCRIPTION OF THE DRAWINGS

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

FIG. 1 illustrates an example of an environment including a memory device.

FIG. 2 illustrates an example of a system that implements accelerated memory device trim initialization.

FIG. 3 illustrates an example of a control flow for a NAND device in which a controller signaled responsibility to load trims.

FIG. 4 illustrates an example of a control flow for a NAND device in which a controller signaled partial responsibility to load trims.

FIG. 5 illustrates a flowchart of a method for accelerated memory device trim initialization.

FIG. 6 is a block diagram illustrating an example of a machine upon which one or more embodiments can be implemented.

### DETAILED DESCRIPTION

Some memory devices, such as NAND devices, have variations in operation of storage cells. These variations can occur during manufacture or during wear throughout the life of the device. Because the tolerances on read and writing techniques (e.g., voltages in NAND devices) have little margin for error, the variations in device operation are addressed through small adjustments called trims to enable robust, accurate, and consistent data storage. A trim is a value or parameter used by hardware or firmware to change electronic functionality such as speed, power, endurance, reliability, etc. A modern NAND device can include thousands of trims to tune the underlying NAND array. Although trims can be used for different kinds of memory devices—such as storage class memory (e.g., using phase change devices, memristors, ferroelectric RAM, etc.) or holographic RAM (HRAM)—the examples below use NAND devices for clarity. The following techniques can generally be applied to any memory device that relies on trims for correct or more performant operation.

Generally, when a NAND array is powered-up, controller circuitry in the array (e.g., an array controller) loads trim sets (e.g., from internal ROM or from the NAND array) into volatile memory elements (e.g., latches) to ensure proper reading and writing of the array. Here, the array controller is distinct from a memory controller for the memory device even if they are packaged together (e.g., as is the case in a managed NAND device). The array controller generally includes few processing or volatile memory resources and is designed to effectuate (e.g., orchestrate) directed reading and writing upon the NAND array. Due to these limited resources, as the complexity of and size of the NAND array increases and the corresponding trim set sizes increase, it takes longer and longer for the array controller to loads the trims for the NAND array. This problem can be exacerbated when the trims are stored within the array itself. Fluctuations in NAND cell operation—such as wear, cross-temperature writing and reading, read disturb conditions, etc.—or simply a higher raw bit error rate (RBER) than other media, can involve error correction operations to correct the stored data before it can be used. The limited processing capabilities of most array controllers in these circumstances can further increase initialization latencies. As a further complication, in some multi-die (e.g., multi-array) devices, a limited power budget can require staggered initialization of the NAND arrays in order to avoid higher current peaks or averages during startup, again increasing startup latency.

Different types of devices have different sensitivities to the startup time of its memory device. Several classes of power-constrained devices can be quite sensitive to startup latencies because they often seek to frequently power down components to conserve limited energy resources. Such devices can include battery operated sensors or actuators (e.g., as is often seen in Internet-of-Things (IoT)), or mobile devices such as phone and tablet computers. For the mobile devices, extended startup latency for the memory device can impact user experiences, as well as limit how aggressively the mobile device can manage its power consumption. Thus, the initialization of memory devices for the mobile devices, including initial trim loading, is an ongoing concern for the industry.

To address these issues, a hybrid array controller and memory controller trim loading technique is described below. Typically, the memory controller has greater computational resources to process raw trim set data into useable trims, for example, via more sophisticated or faster error correction. Further, memory controllers often include fast static memory resources (e.g., SRAM) to retain some parameters. These fast static memory resources often are significantly larger than those that can be found in some array controllers. These features enable a more efficient trim loading procedure in which some of all of the trims are loaded by the memory controller and not the array controller. The memory controller trim loading techniques can be embodied in one or more accelerated trim (e.g., turbo init) commands that communicate deviations from the traditional trim loading procedure to the array controller.

The generally greater processing power of the memory controller can drastically increase trim set data read by leveraging the more sophisticated error correction of the memory controller. Further, the local storage of trims between sleep and wake cycles by the memory controller can further decrease start-up latencies. Additionally, some device interfaces support direct access to NAND latches, further reducing the time used for the memory controller to set trims for which it has taken responsibility away from the array controller. Together, these features support the success of energy constrained devices such as mobile phones and the like.

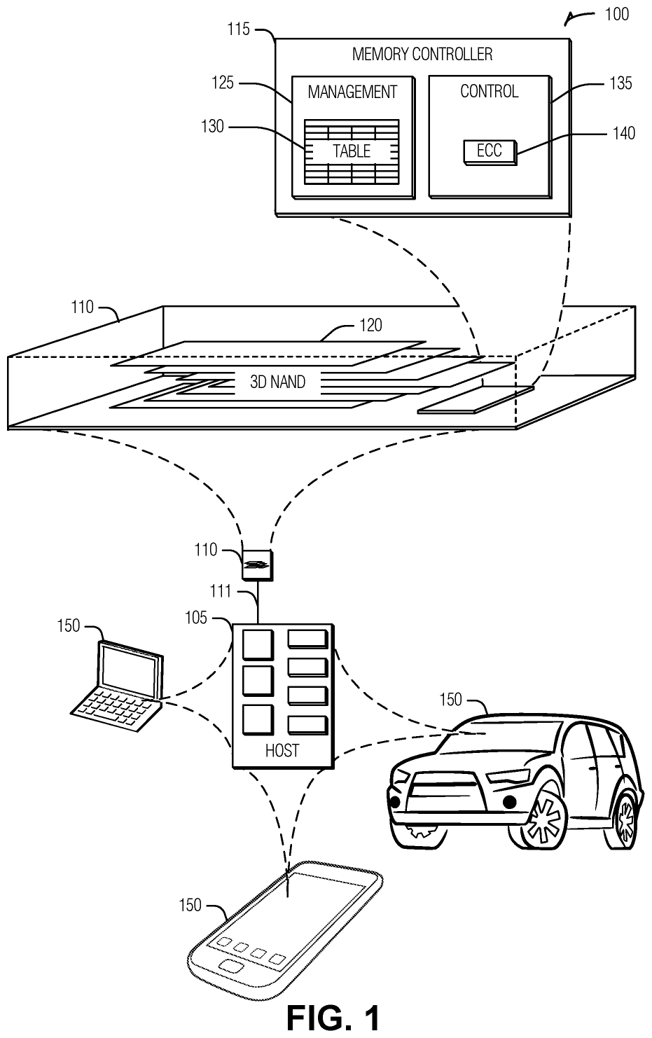

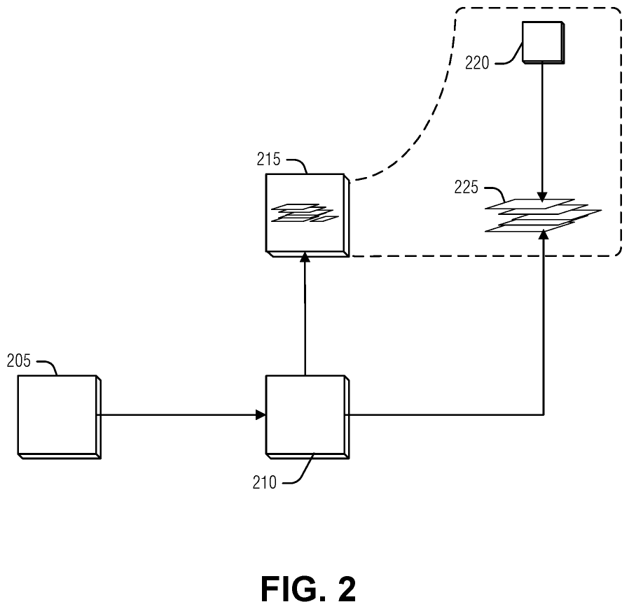

Additional details and examples are provided below. FIG. 1 illustrates an overview of a managed NAND memory device that includes a memory controller and an array controller in the same package. Such an arrangement is not required, however, with possible arrangements including the memory controller as part of the host communicatively coupled to the array controller in a discrete package when they are in operation. FIG. 2 illustrates such a separate arrangement, as well as discussing greater details of the array controller and the memory controller to implement accelerated memory device trim initialization in the NAND flash context.

FIG. 1 illustrates an example of an environment 100 including a host device 105 and a memory device 110 configured to communicate over a communication interface. The host device 105 or the memory device 110 can be included in a variety of products 150, such as Internet of Things (IoT) devices (e.g., a refrigerator or other appliance, sensor, motor or actuator, mobile communication device, automobile, drone, etc.) to support processing, communications, or control of the product 150. FIG. 2 provides details more specific to the adjustable NAND write performance using pSLC encoding.

The memory device 110 includes a memory controller 115 and a memory array 120 including, for example, a number of individual memory die (e.g., a stack of three-dimensional (3D) NAND die). In 3D architecture semiconductor memory technology, vertical structures are stacked, increasing the number of tiers, physical pages, and accordingly, the density of a memory device (e.g., a storage device). In an example, the memory device 110 can be a discrete memory or storage device component of the host device 105. In other examples, the memory device 110 can be a portion of an integrated circuit (e.g., system on a chip (SOC), etc.), stacked or otherwise included with one or more other components of the host device 105. In these examples, the memory device 110 communicates with host device 105 components via an interlink 111, such as a bus. Thus, as described herein, a host, or host device 105 operation is distinct from those of the memory device 110, even when the memory device 110 is integrated into the host device 105.

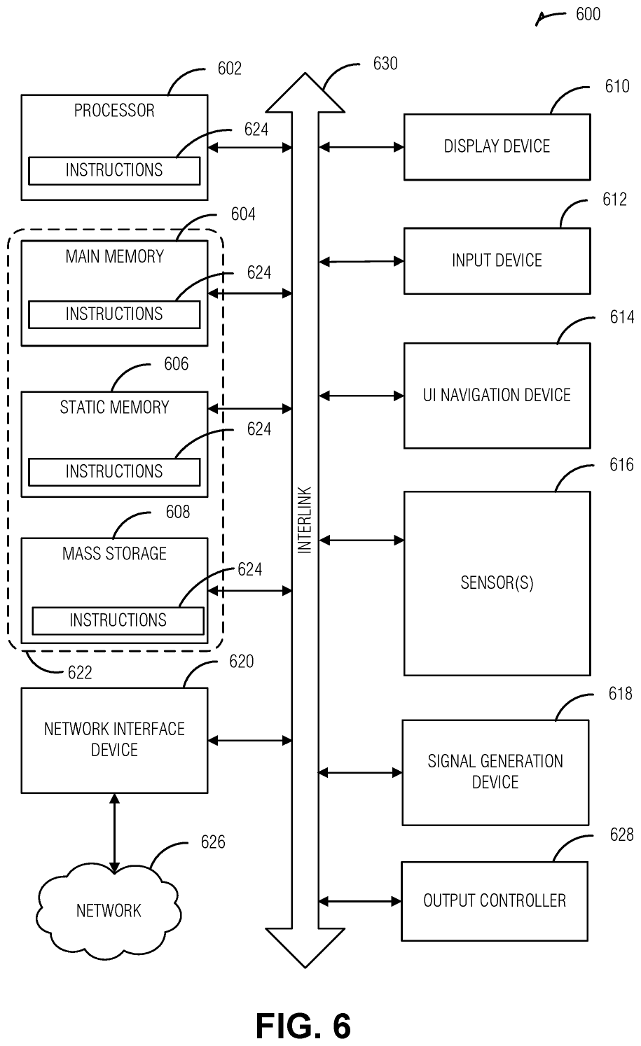

One or more communication interfaces (e.g., the interlink 111) can be used to transfer data between the memory device 110 and one or more other components of the host device 105, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host device 105 can include a host system, an electronic device, a processor, a memory card reader, or one or more other electronic devices external to the memory device 110. In some examples, the host 105 can be a machine having some portion, or all, of the components discussed in reference to the machine 600 of FIG. 6.

The memory controller 115 can receive instructions from the host 105, and can communicate with the memory array 120, such as to transfer data to (e.g., write or erase) or from (e.g., read) one or more of the memory cells, planes, sub-blocks, blocks, or pages of the memory array 120. The memory controller 115 can include, among other things, circuitry or firmware, including one or more components or integrated circuits. For example, the memory controller 115 can include one or more memory control units, circuits, or components configured to control access across the memory array 120 and to provide a translation layer between the host 105 and the memory device 110. Although the memory controller 115 is here illustrated as part of the memory device 110 package, other configurations can be employed, such as the memory controller 115 being a component of the host 105 (e.g., as a discrete package on a system-on-a-chip of the host 105 that is separate from the memory service 110), or even implemented via a central processing unit (CPU) of the host 105.

The memory manager 125 can include, among other things, circuitry or firmware, such as several components or integrated circuits associated with various memory management functions. For purposes of the present description example memory operation and management functions will be described in the context of NAND memory. Persons skilled in the art will recognize that other forms of non-volatile memory can have analogous memory operations or management functions. Such NAND management functions include wear leveling (e.g., garbage collection or reclamation), error detection or correction, block retirement, or one or more other memory management functions. The memory manager 125 can parse or format host commands (e.g., commands received from a host) into device commands (e.g., commands associated with operation of a memory array, etc.), or generate device commands (e.g., to accomplish various memory management functions) for the array controller 135 or one or more other components of the memory device 110.

The memory manager 125 can include a set of management tables 130 configured to maintain various information associated with one or more component of the memory device 110 (e.g., various information associated with a memory array or one or more memory cells coupled to the memory controller 115). For example, the management tables 130 can include information regarding block age, block erase count, error history, or one or more error counts (e.g., a write operation error count, a read bit error count, a read operation error count, an erase error count, etc.) for one or more blocks of memory cells coupled to the memory controller 115. In certain examples, if the number of detected errors for one or more of the error counts is above a threshold, the bit error can be referred to as an uncorrectable bit error. The management tables 130 can maintain a count of correctable or uncorrectable bit errors, among other things. In an example, the management tables 103 can include translation tables or a logical-to-physical (L2P) mapping.

The array controller 135 can include, among other things, circuitry or components configured to control memory operations associated with writing data to, reading data from, or erasing one or more memory cells of the memory device 110 coupled to the memory controller 115. The memory operations can be based on, for example, host commands received from the host 105, or internally generated by the memory manager 125 (e.g., in association with wear leveling, error detection or correction, etc.).

The array controller 135 can include an error correction code (ECC) component 140, which can include, among other things, an ECC engine or other circuitry configured to detect or correct errors associated with writing data to or reading data from one or more memory cells of the memory device 110 coupled to the memory controller 115. The memory controller 115 can be configured to actively detect and recover from error occurrences (e.g., bit errors, operation errors, etc.) associated with various operations or storage of data based on the ECC data maintained by the array controller 135. This enables the memory controller 115 to maintain integrity of the data transferred between the host 105 and the memory device 110 or maintain integrity of stored data. Part of this integrity maintenance can include removing (e.g., retiring) failing memory resources (e.g., memory cells, memory arrays, pages, blocks, etc.) to prevent future errors. RAIN is another technique that can be employed by the memory device 110 to maintain data integrity. The array controller 135 can be arranged to implement RAIN parity data generation and storage in the array 120. The memory controller 115 can be involved in using the parity data to reconstruct damaged data.

The memory array 120 can include several memory cells arranged in, for example, a number of devices, planes, sub-blocks, blocks, or pages. As one example, a 48 GB TLC NAND memory device can include 18,592 bytes (B) of data per page (16,384+2208 bytes), 1536 pages per block, 548 blocks per plane, and 4 or more planes per device. As another example, a 32 GB MLC memory device (storing two bits of data per cell (i.e., 4 programmable states)) can include 18,592 bytes (B) of data per page (16,384+2208 bytes), 1024 pages per block, 548 blocks per plane, and 4 planes per device, but with half the required write time and twice the program/erase (P/E) cycles as a corresponding TLC memory device. Other examples can include other numbers or arrangements. In some examples, a memory device, or a portion thereof, can be selectively operated in SLC mode, or in a desired MLC mode (such as TLC, QLC, etc.).

In operation, data is typically written to or read from the NAND memory device 110 in pages, and erased in blocks. However, one or more memory operations (e.g., read, write, erase, etc.) can be performed on larger or smaller groups of memory cells, as desired. The data transfer size of a NAND memory device 110 is typically referred to as a page, whereas the data transfer size of a host is typically referred to as a sector.

Although a page of data can include a number of bytes of user data (e.g., a data payload including a number of sectors of data) and its corresponding metadata, the size of the page often refers only to the number of bytes used to store the user data. As an example, a page of data having a page size of 4 KB can include 4 KB of user data (e.g., 8 sectors assuming a sector size of 512 B) as well as a number of bytes (e.g., 32 B, 54 B, 224 B, etc.) of metadata corresponding to the user data, such as integrity data (e.g., error detecting or correcting code data), address data (e.g., logical address data, etc.), or other metadata associated with the user data.

Different types of memory cells or memory arrays 120 can provide for different page sizes, or can require different amounts of metadata associated therewith. For example, different memory device types can have different bit error rates, which can lead to different amounts of metadata necessary to ensure integrity of the page of data (e.g., a memory device with a higher bit error rate can require more bytes of error correction code data than a memory device with a lower bit error rate). As an example, a multi-level cell (MLC) NAND flash device can have a higher bit error rate than a corresponding single-level cell (SLC) NAND flash device. As such, the MLC device can require more metadata bytes for error data than the corresponding SLC device.

FIG. 2 illustrates an example of a system that implements accelerated NAND trim initialization. For illustrates purposes, the memory controller 210 is illustrated as separate from the NAND die 215 that includes the array controller 220 and NAND array 225 elements. However, either the configuration described above with respect to FIG. 1 or this configuration can be used for accelerated trim initialization. In either case, the host 205 generally communicates with the memory controller 210 to accomplish read or write operations on the array 225.

The following examples are in the context of the host 205 waking the NAND die 215 for reading or writing. As noted above, in a mobile device, this sequence can occur frequently to manage energy consumption by the device.

Upon being powered on, the NAND die 215 starts its initialization procedure. In a traditional initialization procedure, the array controller 220 is configured to acquire trims and load them into controller structures (e.g., latches) of the array 225 to adjust (e.g., tweak) read or write voltages.

The memory controller 210 is arranged to send an accelerated trim command to the array controller 220, which the array controller 220 is configured to recognize. It is via this accelerated trim command that the array controller 220 is made aware the traditional initialization procedure will be altered. In an example, the accelerated trim command is one of two types of accelerated trim commands, with the first type being a partial type and the second type being a complete type. More details of these two types are described below, however, it is sufficient to understand that the partial type implies that the array controller 220 will be responsible for loading some, but not all, trims—the remaining trims being handled by the memory controller 210—and the complete type implies that the memory controller 210 will process and load all of the trims that will be set.

In response to receiving the accelerated trim command, the array controller 220 is configured to refrain from setting at least one trim. It is this trim that will be set by the memory controller 210. This sequence is a deviation from traditional memory device initialization procedures. In an example, when the accelerated trim command is a complete type, the array controller 220 refrains from initializing from initializing all trims. Again, in this circumstance, the memory controller 210 is signaling to the array controller 220 that the memory controller 210 will set all of the trims, and thus the array controller 220 does not process the trims at all.

In an example, when the accelerated trim command is a partial type, the array controller 220 refrains from initializing a subset of all trims. Thus, here, the array controller 220 initializes some trims, but not others. In an example, the subset of all trims are trims that are not specific to the NAND die 215. In an example, the array controller loads trims that are specific to the NAND die. Such trims can include those determined at the time of manufacture for the NAND die 215 and encoded in a ROM or other reliable storage media of the NAND die 215. Here, non-specific NAND die trims can include those that are the result of NAND cell wear in the array 225, cross temperature situations (e.g., trim adjustments based on the ambient temperature of the NAND die 215), or other variable trims that can change over time. This bifurcated responsibility can benefit the overall trim loading procedure by enabling the array controller 220 to load only trims that are unique to that array and memory controller 210 to transmit other common trims in parallel to multiple NAND die 215 of the system or by enabling the array controller 220 to only load the trims necessary to read the rest and pass them to memory controller 210 for errors correction.

Once the trims are set by the memory controller 210, the array controller 220 completes the initialization of the NAND die. In an example, the memory controller 210 is configured to send an enable trim command to the array controller 220 to signal that the memory controller 210 is done setting the trims for which it has taken responsibility. Thus, to move forward with completing the initialization, the array controller 220 is arranged to wait until it receives the enable trims command.

There are circumstances in which the memory controller 210 fails to load the trims for which it had initially taken responsibility. Thus, in an example, upon failure to load a trim, the memory controller 210 is arranged to provide an error type of accelerated trim command. This command specifies that a previous trim loading operation failed. In an example, the command includes an indication of which trims were not loaded as part of the failure. The array controller 220, upon receipt of the error type accelerated trim command, is configured to set the trims that the memory controller 210 failed to load. Thus, a graceful fallback to the traditional trim loading procedure is accomplished if the memory controller 210 fails to load a trim. In this context, the memory controller 210 or the host 205 can be configured to verify loaded trims via a parity check, or by reading back loaded trims and comparing them to expected values.

With respect to trim storage, several options are available. As noted above, the memory controller 210 can be configured to store the trims within itself, in fact static storage media. This option can be useful between sleep and wake cycles of a device, such as a mobile phone. In an example, the array controller 220 can be configured to store trims in the array 225 and provide them to the memory controller 210 upon request. This arrangement is useful when, for example, the device is shut down and the memory controller's fast static media is cleared. It can also be useful when the memory controller 210 uses its fast static storage media for other purposes, evicting trim data.

Thus, in an example, the memory controller 210 is configured to issue a trim read command for the raw trim data (e.g., before error correction has been applied) to the array controller 220 and the array controller 220 is configured to provide the raw trim data in response. In an example, the trim read command does not specify an address. Often, it is not necessary for the memory controller 210 to specify the trim location within the array 225 because the array controller 220 is already aware of where the trim data is to, for example, perform the trim loading itself. Thus, omitting the trim data location reduces overhead in the trim read command. In an example, a location in the array 225 where the trim data is stored is not addressable by an issuer of the trim read command. This arrangement reduces the likelihood that the trim data is inadvertently, or maliciously, tampered with.

Several occur when using the accelerated trim loading techniques described herein. Examples of these benefits include improved system performance by latency reduction, resulting in improved system responsiveness. This benefit is accentuated in energy constrained systems that can now take a more aggressive power management stance while maintaining the same level of user experience. Further, trim accuracy (e.g., reliability) is improved by the use of more sophisticated error correction techniques. These benefits result in better overall device performance for devices that include accelerated trim initialization.

The following are an example of a set of accelerated trim commands that the memory controller 210 can issue to the array controller. This set of commands can include F1h (skip load), F2h (first partial trim loading), F3h (second partial trim loading), 0F-30h (alternative and compact trim loading), and F0h (enable trims).

F1h: Skip loading. The command signals to the array controller 220 to not to perform the traditional “on first call trim loading procedure.” This is an example of a complete type of accelerated trim loading command. FIG. illustrates an example of F1h.

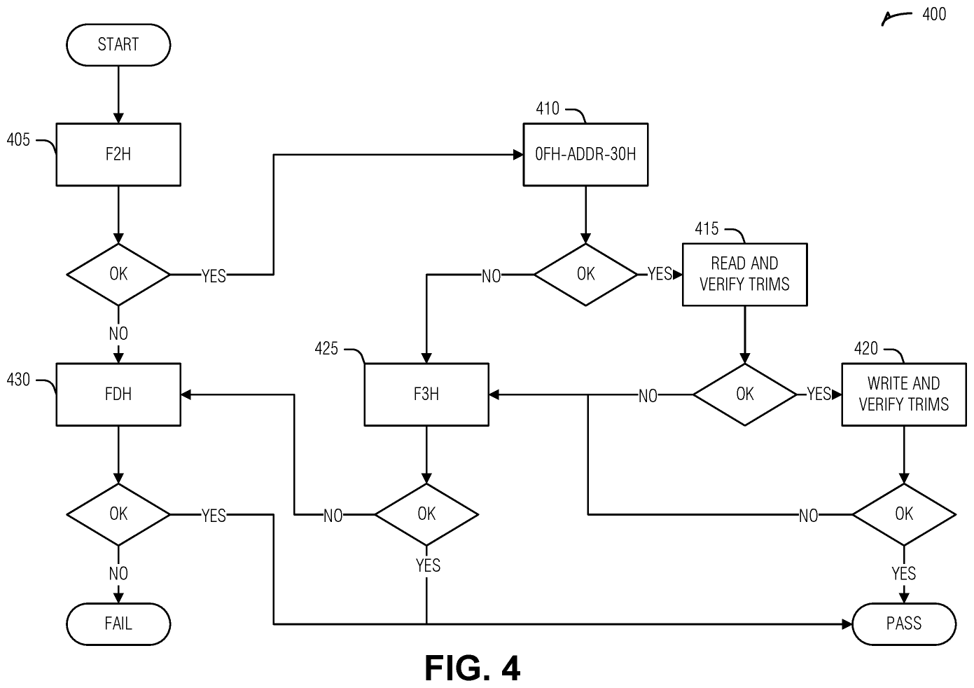

F2h: First Partial Trim Loading. Similar to F1h, F2h interrupts the array controller's traditional trim loading procedure. However, F2h specifies that the array controller 220 is to load a basic set of trims to allow an optimized execution of the alternative trim loading. Examples of these basic set of trims can include Analog, Column and Row Redundancy, Zq, Open NAND Flash Interface (ONFI) trims. These trims can be considered NAND die specific trims. F2h is an example of a partial type of accelerated NAND trim command. FIG. 4 illustrates an example of F2h.

F3h: Second Partial Trim Loading. F3h operates as a complement of F2h with respect to FDh (e.g., traditional array controller 220 trim loading procedure) to signal to the array controller 220 to quickly complete initialization of a trim if F2h failed. Thus, F3h is an example of an error type accelerated trim initialization command.

0F-30h: Alternative and Compact Trim Loading. This command is a trim read command issued by the memory controller 210. Depending on implementation, 0F-30h can specify different read characteristics used by the array controller 220 when reading the array to provide different levels of read reliability (e.g., faster and possibly requiring more error correction or slower and possibly requiring less error correction) or storage location (e.g., accessing a special block such as a different page on the ROM block or a “semi-good” tagged block.

F0h: Enable Trims. F0h is issued by the memory controller 210 to trigger reg_romfuse_en signals in the array controller 220, after which the array controller 220 completes the initialization operations.

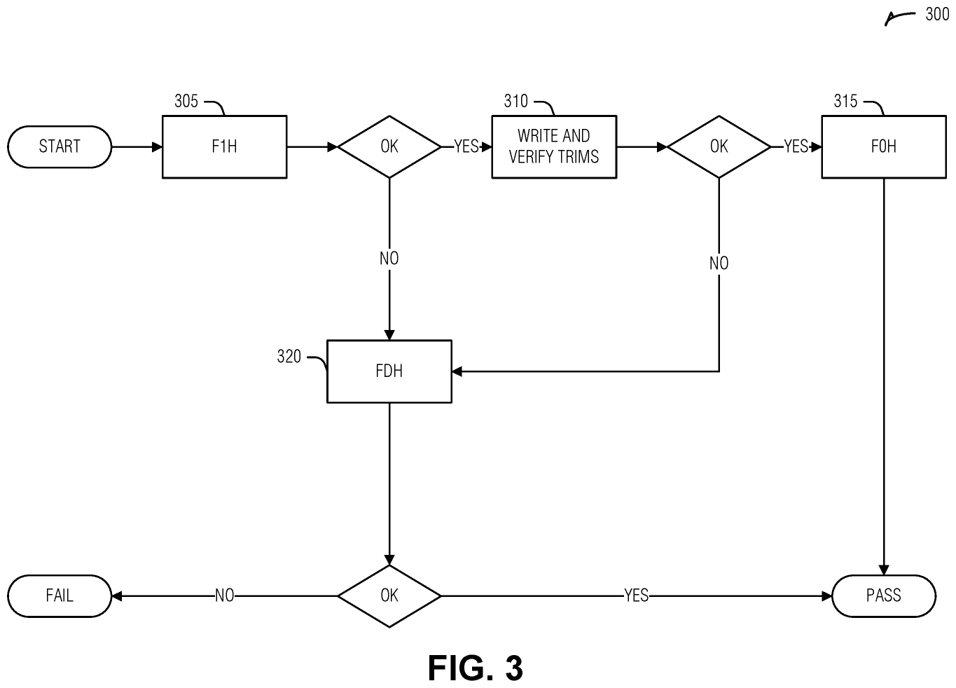

FIG. 3 illustrates an example of a control flow 300 for a NAND device in which a controller signaled responsibility to load trims. Assume that the NAND device is coming out of a sleep state. In this power state, e.g., as defined in the Universal Flash Storage (UFS) specification, the Power Management Integrated Circuit (PMIC) can disconnect Vcc (e.g., the NAND core power supply) and leave Vccq enabled (e.g., the UFS controller still ON). To accelerate the NAND device re-initialization at resume, the memory controller can store the NAND trims in the memory controller's retention SRAM (e.g., few kilobytes of storage) and reload the trims using turbo init commands.

For example, the memory controller can issue the F1h command to stop the array controller from loading trims (operation 305). If F1h is unsuccessful (e.g., the array controller does not understand the command or some other error occurs), the array controller proceeds to the traditional trim loading sequence (operation 320). If F1h succeeds, then the memory controller loads and verifies all of the trims (operation 310). If the trim loading is successful, then the memory controller issues the F0h (enable trims) command to the array controller which completes the initialization (operation 315). Otherwise, the array controller completes the traditional trim loading procedure (operation 320). The FDh command (operation 320) can be subject to trim verification that can lead to a good state (e.g., pass) or a bad state (e.g., fail). In the pass state, the NAND device is ready for use by the host, for example.

In an example, if an ONFI configuration is lost when Vcc is disabled, F1h can include loading the ONFI configuration. In an example, an MLBi phase can be split into two segments, where the first segment is a trim write and verification and the second segment enables ONFI after the first segment completes.

FIG. 4 illustrates an example of a control flow 400 for a NAND device in which a controller signaled partial responsibility to load trims. As noted above, an example of F2h partial trim loading is illustrated in FIG. 4. A NAND array (e.g., die) can be split into different segments (e.g., pages, planes, blocks, etc.). In an example, each segment has its own set of trims. However, there are some trims that are common to all NAND arrays for a NAND device and some are specific. In an example, during F2h operation, the array controller loads these die specific trims. Such dies specific trims can be smaller than other trims, resulting in quick completion by the array controller.

Thus, the control flow 400 begins with the memory controller issuing the F2h command to the array controller (operation 405), signaling the array controller that the array controller is responsible for some trims (e.g., die specific trims) and the memory controller is responsible for other trims. As in control flow 300 above, if the F2h command fails, the array controller uses the traditional trim loading procedure (operation 430).

If the F2h command is accepted by the array controller, then the memory controller issues a trim read command (operation 410). If this trim read command fails, the memory controller uses the F3h command (operation 425) to signal that the array controller should complete trim loading from where the memory controller left off. If this fails, the array controller falls back on the traditional trim loading procedure (operation 430). F3h is the failure path should the memory controller fail to address (operation 410), read (operation 415), or write (operation 420) any trims during the F2h operation. If the read (operation 415) is successful, then the memory controller can use the trim data and modify it based on certain conditions, and then write it (operation 420) to the array controller to modify the trims used by the memory.

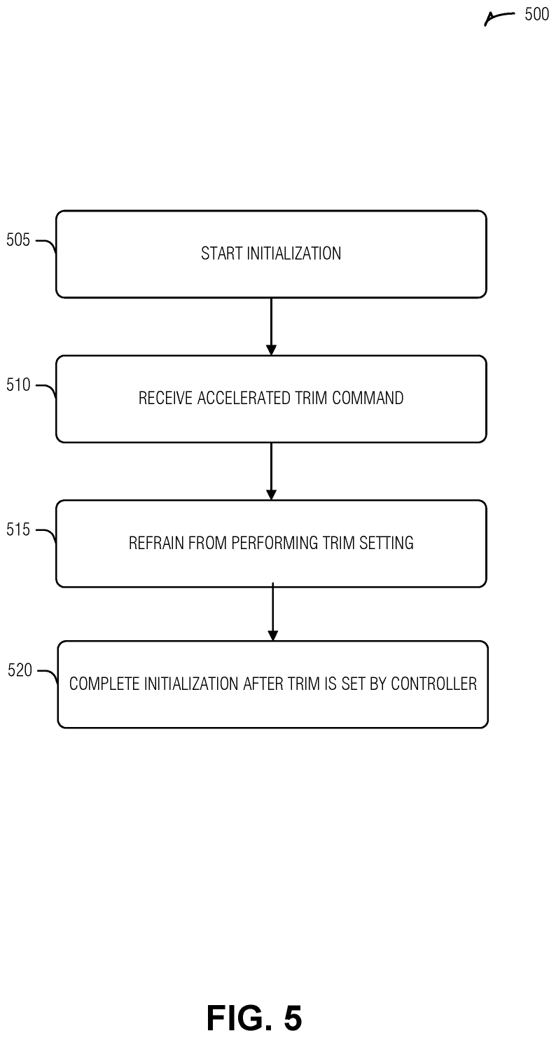

FIG. 5 illustrates a flowchart of a method 500 for accelerated memory device trim initialization. The operations of the method are implemented in computer hardware, such as that described above (e.g., an array controller, etc.) or below (e.g., processing circuitry).

At operation 505, a memory device starts its initialization.

At operation 510, the memory device receives an accelerated trim command from a controller. In an example, the accelerated trim command is one of two types of accelerated trim commands where a first type is a partial type and a second type is a complete type.

At operation 515, the memory device refrains from setting a trim in response to receipt of the accelerated trim command. Here, the trim will be set by the controller. In an example, when the accelerated trim command is a complete type, the array refrains from initializing from initializing all trims.

In an example, when the accelerated trim command is a partial type, the array refrains from initializing a subset of all trims. In an example, the subset of all trims are trims that are not specific to the memory device. In an example, the method 500 is extended to include the memory device loading trims that are specific to the memory device.

At operation 520, the memory device completes the initialization after the trim is set by the controller. In an example, to move forward with completing the initialization, the memory device receives an enable trim command from the controller to signal that the trim has been set by the controller.

In an example, the operations of the method 500 can be extended to include fallback operations in the case when a previous attempt to load trims by the controller did not work. These operations can include starting a second initialization of the memory device, receiving a second accelerated trim command—which is a partial type—from the controller, and refraining setting a second trim in response to receipt of the second accelerated trim command. Now, the memory device receives a third accelerated trim command in response to a failure of the controller to set the second trim. The memory device then sets the second trim in response to receipt of the third accelerated trim command and completes the second initialization of the memory device when the second trim is set.

In an example, the method 500 can be extended to include additional operations that enable the memory device to store and provide the raw trim data to the controller. For example, the memory device can receive a trim read command and provide trim data stored on the memory device in response to receipt of the trim read command. In an example, the trim read command does not specify an address. In an example, a location in the memory device where the trim data is stored is not addressable by an issuer of the trim read command.

FIG. 6 illustrates a block diagram of an example machine 600 upon which any one or more of the techniques (e.g., methodologies) discussed herein can perform. In alternative embodiments, the machine 600 can operate as a standalone device or can be connected (e.g., networked) to other machines. In a networked deployment, the machine 600 can operate in the capacity of a server machine, a client machine, or both in server-client network environments. In an example, the machine 600 can act as a peer machine in peer-to-peer (P2P) (or other distributed) network environment. The machine 600 can be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer readable medium is communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time.

The machine (e.g., computer system) 600 (e.g., the host device 105, the memory device 110, etc.) can include a hardware processor 602 (e.g., a central processing unit (CPU), a graphics processing unit (GPU), a hardware processor core, or any combination thereof, such as the memory controller 115, etc.), a main memory 604 and a static memory 606, some or all of which can communicate with each other via an interlink (e.g., bus) 608. The machine 600 can further include a display unit 610, an alphanumeric input device 612 (e.g., a keyboard), and a user interface (UI) navigation device 614 (e.g., a mouse). In an example, the display unit 610, input device 612 and UI navigation device 614 can be a touch screen display. The machine 600 can additionally include a storage device (e.g., drive unit) 608, a signal generation device 618 (e.g., a speaker), a network interface device 620, and one or more sensors 616, such as a global positioning system (GPS) sensor, compass, accelerometer, or other sensor. The machine 600 can include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 608 can include a machine readable medium 622 on which is stored one or more sets of data structures or instructions 624 (e.g., software) embodying or utilized by any one or more of the techniques or functions described herein. The instructions 624 can also reside, completely or at least partially, within the main memory 604, within static memory 606, or within the hardware processor 602 during execution thereof by the machine 600. In an example, one or any combination of the hardware processor 602, the main memory 604, the static memory 606, or the storage device 608 can constitute the machine readable medium 622.

While the machine readable medium 622 is illustrated as a single medium, the term “machine readable medium” can include a single medium or multiple media (e.g., a centralized or distributed database, or associated caches and servers) configured to store the one or more instructions 624.

The term “machine readable medium” can include any medium that is capable of storing, encoding, or carrying instructions for execution by the machine 600 and that cause the machine 600 to perform any one or more of the techniques of the present disclosure, or that is capable of storing, encoding or carrying data structures used by or associated with such instructions. Non-limiting machine readable medium examples can include solid-state memories, and optical and magnetic media. In an example, a massed machine readable medium comprises a machine-readable medium with a plurality of particles having invariant (e.g., rest) mass. Accordingly, massed machine-readable media are not transitory propagating signals. Specific examples of massed machine readable media can include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 624 (e.g., software, programs, an operating system (OS), etc.) or other data are stored on the storage device 621, can be accessed by the memory 604 for use by the processor 602. The memory 604 (e.g., DRAM) is typically fast, but volatile, and thus a different type of storage than the storage device 621 (e.g., an SSD), which is suitable for long-term storage, including while in an “off” condition. The instructions 624 or data in use by a user or the machine 600 are typically loaded in the memory 604 for use by the processor 602. When the memory 604 is full, virtual space from the storage device 621 can be allocated to supplement the memory 604; however, because the storage 621 device is typically slower than the memory 604, and write speeds are typically at least twice as slow as read speeds, use of virtual memory can greatly reduce user experience due to storage device latency (in contrast to the memory 604, e.g., DRAM). Further, use of the storage device 621 for virtual memory can greatly reduce the usable lifespan of the storage device 621.

In contrast to virtual memory, virtual memory compression (e.g., the Linux® kernel feature “ZRAM”) uses part of the memory as compressed block storage to avoid paging to the storage device 621. Paging takes place in the compressed block until it is necessary to write such data to the storage device 621. Virtual memory compression increases the usable size of memory 604, while reducing wear on the storage device 621.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival serial ATA™ (Serial AT (Advanced Technology) Attachment, or SATA) based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

The instructions 624 can further be transmitted or received over a communications network 626 using a transmission medium via the network interface device 620 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks) such as those defined by the Third Generation Partnership Project (3GPP) families of standards (e.g., 3G, 4G, 5G, Long Term Evolution (LTE), etc.), Plain Old Telephone (POTS) networks, and wireless data networks (e.g., Institute of Electrical and Electronics Engineers (IEEE) 802.11 family of standards known as Wi-Fi®), IEEE 802.15.4 family of standards, peer-to-peer (P2P) networks, among others. In an example, the network interface device 620 can include one or more physical jacks (e.g., Ethernet, coaxial, or phone jacks) or one or more antennas to connect to the communications network 626. In an example, the network interface device 620 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that can store, encoding or carrying instructions for execution by the machine 600, and includes digital or analog communications signals or other intangible medium to facilitate communication of such software.

### ADDITIONAL EXAMPLES

Example 1 is a memory device for accelerated memory device trim initialization, the memory device comprising: an interface to receive an accelerated trim command from a controller; and processing circuitry to: start an initialization of the memory device; refrain from setting a trim in response to receipt of the accelerated trim command, the trim being set by the controller; and complete, after the trim is set by the controller, the initialization of the memory device.

In Example 2, the subject matter of Example 1, wherein the accelerated trim command is one of two types of accelerated trim commands, a first type being a partial type and a second type being a complete type.

In Example 3, the subject matter of Example 2, wherein the accelerated trim command is a complete type, and wherein, to refrain from setting a trim, the processing circuitry is configured to refrain from setting all trims.

In Example 4, the subject matter of any of Examples 2-3, wherein the accelerated trim command is a partial type, and wherein, to refrain from setting a trim, the processing circuitry is configured to refrain from setting a subset of all trims.

In Example 5, the subject matter of Example 4, wherein the subset of all trims are trims that are not specific to the memory device.

In Example 6, the subject matter of Example 5, wherein the processing circuitry is configured to load trims specific to the memory device.

In Example 7, the subject matter of any of Examples 4-6, wherein the interface is configured to receive: a second accelerated trim command from the controller, the second accelerated trim command being a partial type; and a third accelerated trim command in response to a failure of the controller to set a second trim; and wherein the processing circuitry is configured to: start a second initialization of the memory device; refrain from setting the second trim in response to receipt of the second accelerated trim command; set the second trim in response to receipt of the third accelerated trim command; and complete, after the second trim is set, the second initialization of the memory device.

In Example 8, the subject matter of any of Examples 1-7, wherein the interface is configured to receive an enable trim command from the controller to signal that the trim has been set by the controller, and wherein the processing circuitry is configured to complete the initialization of the memory device after receipt of the enable trim command.

In Example 9, the subject matter of any of Examples 1-8, wherein the interface is configured to receive a trim read command, and wherein the processing circuitry is configured to provide trim data stored on the memory device in response to receipt of the trim read command.

In Example 10, the subject matter of Example 9, wherein the trim read command does not specify an address.

In Example 11, the subject matter of any of Examples 9-10, wherein a location in the memory device where the trim data is stored is not addressable by an issuer of the trim read command.

Example 12 is a method for accelerated memory device trim initialization, the method comprising: starting, at a memory device, an initialization of the memory device; receiving, at the memory device, an accelerated trim command from a controller; refraining, by the memory device, from setting a trim in response to receipt of the accelerated trim command, the trim being set by the controller; and completing, by the memory device after the trim is set by the controller, the initialization of the memory device.

In Example 13, the subject matter of Example 12, wherein the accelerated trim command is one of two types of accelerated trim commands, a first type being a partial type and a second type being a complete type.

In Example 14, the subject matter of Example 13, wherein the accelerated trim command is a complete type, and wherein refraining from setting a trim includes refraining from setting all trims.

In Example 15, the subject matter of any of Examples 13-14, wherein the accelerated trim command is a partial type, and wherein refraining from setting a trim includes refraining from setting a subset of all trims.

In Example 16, the subject matter of Example 15, wherein the subset of all trims are trims that are not specific to the memory device.

In Example 17, the subject matter of Example 16, comprising, loading, by the memory device, trims specific to the memory device.

In Example 18, the subject matter of any of Examples 15-17, comprising: starting, at the memory device, a second initialization of the memory device; receiving, at the memory device, a second accelerated trim command from the controller, the second accelerated trim command being a partial type; refraining, by the memory device, from setting a second trim in response to receipt of the second accelerated trim command; receiving, by the memory device, a third accelerated trim command in response to a failure of the controller to set the second trim; setting, by the memory device, the second trim in response to receipt of the third accelerated trim command; and completing, by the memory device after the second trim is set, the second initialization of the memory device.

In Example 19, the subject matter of any of Examples 12-18, wherein completing, by the memory device after the trim is set by the controller, the initialization of the memory device includes receiving an enable trim command from the controller to signal that the trim has been set by the controller.

In Example 20, the subject matter of any of Examples 12-19, comprising: receiving, by the memory device, a trim read command; and providing trim data stored on the memory device in response to receipt of the trim read command.

In Example 21, the subject matter of Example 20, wherein the trim read command does not specify an address.

In Example 22, the subject matter of any of Examples 20-21, wherein a location in the memory device where the trim data is stored is not addressable by an issuer of the trim read command.

Example 23 is a machine readable medium including instructions for accelerated memory device trim initialization, the instructions, when executed by processing circuitry, cause the processing circuitry to perform operations comprising: starting, at a memory device, an initialization of the memory device; receiving, at the memory device, an accelerated trim command from a controller; refraining, by the memory device, from setting a trim in response to receipt of the accelerated trim command, the trim being set by the controller; and completing, by the memory device after the trim is set by the controller, the initialization of the memory device.

In Example 24, the subject matter of Example 23, wherein the accelerated trim command is one of two types of accelerated trim commands, a first type being a partial type and a second type being a complete type.

In Example 25, the subject matter of Example 24, wherein the accelerated trim command is a complete type, and wherein refraining from setting a trim includes refraining from setting all trims.

In Example 26, the subject matter of any of Examples 24-25, wherein the accelerated trim command is a partial type, and wherein refraining from setting a trim includes refraining from setting a subset of all trims.

In Example 27, the subject matter of Example 26, wherein the subset of all trims are trims that are not specific to the memory device.

In Example 28, the subject matter of Example 27, wherein the operations comprise loading, by the memory device, trims specific to the memory device.

In Example 29, the subject matter of any of Examples 26-28, wherein the operations comprise: starting, at the memory device, a second initialization of the memory device; receiving, at the memory device, a second accelerated trim command from the controller, the second accelerated trim command being a partial type; refraining, by the memory device, from setting a second trim in response to receipt of the second accelerated trim command; receiving, by the memory device, a third accelerated trim command in response to a failure of the controller to set the second trim; setting, by the memory device, the second trim in response to receipt of the third accelerated trim command; and completing, by the memory device after the second trim is set, the second initialization of the memory device.

In Example 30, the subject matter of any of Examples 23-29, wherein completing, by the memory device after the trim is set by the controller, the initialization of the memory device includes receiving an enable trim command from the controller to signal that the trim has been set by the controller.

In Example 31, the subject matter of any of Examples 23-30, wherein the operations comprise: receiving, by the memory device, a trim read command; and providing trim data stored on the memory device in response to receipt of the trim read command.

In Example 32, the subject matter of Example 31, wherein the trim read command does not specify an address.

In Example 33, the subject matter of any of Examples 31-32, wherein a location in the memory device where the trim data is stored is not addressable by an issuer of the trim read command.

Example 34 is a system for accelerated memory device trim initialization, the system comprising: means for starting, at a memory device, an initialization of the memory device; means for receiving, at the memory device, an accelerated trim command from a controller; means for refraining, by the memory device, from setting a trim in response to receipt of the accelerated trim command, the trim being set by the controller; and means for completing, by the memory device after the trim is set by the controller, the initialization of the memory device.

In Example 35, the subject matter of Example 34, wherein the accelerated trim command is one of two types of accelerated trim commands, a first type being a partial type and a second type being a complete type.

In Example 36, the subject matter of Example 35, wherein the accelerated trim command is a complete type, and wherein the means for refraining from setting a trim include means for refraining from setting all trims.

In Example 37, the subject matter of any of Examples 35-36, wherein the accelerated trim command is a partial type, and wherein the means for refraining from setting a trim include means for refraining from setting a subset of all trims.

In Example 38, the subject matter of Example 37, wherein the subset of all trims are trims that are not specific to the memory device.

In Example 39, the subject matter of Example 38, comprising, loading, by the memory device, trims specific to the memory device.

In Example 40, the subject matter of any of Examples 37-39, comprising: means for starting, at the memory device, a second initialization of the memory device; means for receiving, at the memory device, a second accelerated trim command from the controller, the second accelerated trim command being a partial type; means for refraining, by the memory device, from setting a second trim in response to receipt of the second accelerated trim command; means for receiving, by the memory device, a third accelerated trim command in response to a failure of the controller to set the second trim; means for setting, by the memory device, the second trim in response to receipt of the third accelerated trim command; and means for completing, by the memory device after the second trim is set, the second initialization of the memory device.

In Example 41, the subject matter of any of Examples 34-40, wherein the means for completing, by the memory device after the trim is set by the controller, the initialization of the memory device include means for receiving an enable trim command from the controller to signal that the trim has been set by the controller.

In Example 42, the subject matter of any of Examples 34-41, comprising: means for receiving, by the memory device, a trim read command; and means for providing trim data stored on the memory device in response to receipt of the trim read command.

In Example 43, the subject matter of Example 42, wherein the trim read command does not specify an address.

In Example 44, the subject matter of any of Examples 42-43, wherein a location in the memory device where the trim data is stored is not addressable by an issuer of the trim read command.

Example 45 is at least one machine-readable medium including instructions that, when executed by processing circuitry, cause the processing circuitry to perform operations to implement of any of Examples 1-44.

Example 46 is an apparatus comprising means to implement of any of Examples 1-44.

Example 47 is a system to implement of any of Examples 1-44.

Example 48 is a method to implement of any of Examples 1-44.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The terms “wafer” and “substrate” are used herein to refer generally to any structure on which integrated circuits are formed, and also to such structures during various stages of integrated circuit fabrication. The following detailed description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells (e.g., NAND strings of memory cells). As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

Operating a memory cell, as used herein, includes reading from, writing to, or erasing the memory cell. The operation of placing a memory cell in an intended state is referred to herein as “programming,” and can include both writing to or erasing from the memory cell (e.g., the memory cell can be programmed to an erased state).

According to one or more embodiments of the present disclosure, a memory controller (e.g., a processor, controller, firmware, etc.) located internal or external to a memory device, is capable of determining (e.g., selecting, setting, adjusting, computing, changing, clearing, communicating, adapting, deriving, defining, utilizing, modifying, applying, etc.) a quantity of wear cycles, or a wear state (e.g., recording wear cycles, counting operations of the memory device as they occur, tracking the operations of the memory device it initiates, evaluating the memory device characteristics corresponding to a wear state, etc.)

According to one or more embodiments of the present disclosure, a memory access device can be configured to provide wear cycle information to the memory device with each memory operation. The memory device control circuitry (e.g., control logic) can be programmed to compensate for memory device performance changes corresponding to the wear cycle information. The memory device can receive the wear cycle information and determine one or more operating parameters (e.g., a value, characteristic) in response to the wear cycle information.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code can form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact discs and digital video disks), magnetic cassettes, memory cards or sticks, random access memories (RAMS), read only memories (ROMs), solid state drives (SSDs), Universal Flash Storage (UFS) device, embedded MMC (eMMC) device, and the like.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A memory device for accelerated memory device trim initialization, the memory device comprising:
an interface to receive an accelerated trim command from a controller; and
processing circuitry to:
start an initialization of the memory device;
refrain from setting a trim in response to receipt of the accelerated trim command, the trim being set by the controller; and
complete, after the trim is set by the controller, the initialization of the memory device.

2. The memory device of claim 1, wherein the accelerated trim command is one of two types of accelerated trim commands, a first type being a partial type and a second type being a complete type.

3. The memory device of claim 2, wherein the accelerated trim command is a complete type, and wherein, to refrain from setting a trim, the processing circuitry is configured to refrain from setting all trims.

4. The memory device of claim 2, wherein the accelerated trim command is a partial type, and wherein, to refrain from setting a trim, the processing circuitry is configured to refrain from setting a subset of all trims.

5. The memory device of claim 4, wherein the subset of all trims are trims that are not specific to the memory device.

6. The memory device of claim 5, wherein the processing circuitry is configured to load trims specific to the memory device.

7. The memory device of claim 4, wherein the interface is configured to receive:
a second accelerated trim command from the controller, the second accelerated trim command being a partial type; and
a third accelerated trim command in response to a failure of the controller to set a second trim; and
wherein the processing circuitry is configured to:
start a second initialization of the memory device;
refrain from setting the second trim in response to receipt of the second accelerated trim command;
set the second trim in response to receipt of the third accelerated trim command; and
complete, after the second trim is set, the second initialization of the memory device.

8. The memory device of claim 1, wherein the interface is configured to receive a trim read command, and wherein the processing circuitry is configured to provide trim data stored on the memory device in response to receipt of the trim read command.

9. A method for accelerated memory device trim initialization, the method comprising:
starting, at a memory device, an initialization of the memory device;
receiving, at the memory device, an accelerated trim command from a controller;
refraining, by the memory device, from setting a trim in response to receipt of the accelerated trim command, the trim being set by the controller; and
completing, by the memory device after the trim is set by the controller, the initialization of the memory device.

10. The method of claim 9, wherein the accelerated trim command is one of two types of accelerated trim commands, a first type being a partial type and a second type being a complete type.

11. The method of claim 10, wherein the accelerated trim command is a complete type, and wherein refraining from setting a trim includes refraining from setting all trims.

12. The method of claim 10, wherein the accelerated trim command is a partial type, and wherein refraining from setting a trim includes refraining from setting a subset of all trims.

13. The method of claim 12, wherein the subset of all trims are trims that are not specific to the memory device.

14. The method of claim 13, comprising, loading, by the memory device, trims specific to the memory device.

15. The method of claim 12, comprising:
starting, at the memory device, a second initialization of the memory device;
receiving, at the memory device, a second accelerated trim command from the controller, the second accelerated trim command being a partial type;
refraining, by the memory device, from setting a second trim in response to receipt of the second accelerated trim command;
receiving, by the memory device, a third accelerated trim command in response to a failure of the controller to set the second trim;
setting, by the memory device, the second trim in response to receipt of the third accelerated trim command; and
completing, by the memory device after the second trim is set, the second initialization of the memory device.

16. The method of claim 9, comprising:
receiving, by the memory device, a trim read command; and
providing trim data stored on the memory device in response to receipt of the trim read command.

17. A machine readable medium including instructions for accelerated memory device trim initialization, the instructions, when executed by processing circuitry, cause the processing circuitry to perform operations comprising:
starting, at a memory device, an initialization of the memory device;
receiving, at the memory device, an accelerated trim command from a controller;
refraining, by the memory device, from setting a trim in response to receipt of the accelerated trim command, the trim being set by the controller; and
completing, by the memory device after the trim is set by the controller, the initialization of the memory device.

18. The machine readable medium of claim 17, wherein the accelerated trim command is one of two types of accelerated trim commands, a first type being a partial type and a second type being a complete type.

19. The machine readable medium of claim 18, wherein the accelerated trim command is a complete type, and wherein refraining from setting a trim includes refraining from setting all trims.

20. The machine readable medium of claim 18, wherein the accelerated trim command is a partial type, and wherein refraining from setting a trim includes refraining from setting a subset of all trims.

21. The machine readable medium of claim 20, wherein the subset of all trims are trims that are not specific to the memory device.

22. The machine readable medium of claim 21, wherein the operations comprise loading, by the memory device, trims specific to the memory device.

23. The machine readable medium of claim 20, wherein the operations comprise:
starting, at the memory device, a second initialization of the memory device;
receiving, at the memory device, a second accelerated trim command from the controller, the second accelerated trim command being a partial type;
refraining, by the memory device, from setting a second trim in response to receipt of the second accelerated trim command;
receiving, by the memory device, a third accelerated trim command in response to a failure of the controller to set the second trim;
setting, by the memory device, the second trim in response to receipt of the third accelerated trim command; and
completing, by the memory device after the second trim is set, the second initialization of the memory device.

24. The machine readable medium of claim 17, wherein the operations comprise:
receiving, by the memory device, a trim read command; and
providing trim data stored on the memory device in response to receipt of the trim read command.
